(19) United States
(12) Patent Application Publication
(10) Pub. No.: US 2025/0107263 A1
(43) Pub. Date: Mar. 27, 2025

(54) PHOTOELECTRIC SENSING DEVICE

(71) Applicant: InnoCare Optoelectronics Corporation, Tainan City (TW)

(72) Inventor: Hsin-Hung Lin, Tainan City (TW)

(73) Assignee: InnoCare Optoelectronics Corporation, Tainan City (TW)

(21) Appl. No.: 18/805,560

(22) Filed: Aug. 15, 2024

(30) Foreign Application Priority Data
Sep. 27, 2023 (TW) 112136967

(51) Int. Cl. H01L 27/146

(52) U.S. Cl. CPC H10F 39/811; H10F 39/8037

(57) ABSTRACT

A photoelectric sensing device including a substrate, a first pixel structure, a second pixel structure and a first bus line. The first pixel structure is disposed on the substrate and includes a first photoelectric sensing component, wherein the first photoelectric sensing component has a first semiconductor layer. The second pixel structure is disposed on the substrate and includes a second photoelectric sensing component, wherein the second photoelectric sensing component has a second semiconductor layer. The first bus line is disposed on the substrate and located between the first semiconductor layer and the second semiconductor layer, wherein the first bus line is electrically connected to the first pixel structure and the second pixel structure.

### CROSS-REFERENCE TO RELATED APPLICATION

This application claims the priority benefit of Taiwan application serial no. 112136967, filed on Sep. 27, 2023. The entirety of the above-mentioned patent application is hereby incorporated by reference herein and made a part of this specification.

### BACKGROUND

### Technical Field

The disclosure relates to a photoelectric sensing device.

### Description of Related Art

Under the recent trend of smaller photoelectric sensing devices, the photoelectric sensing region and circuit layout region are also reduced, which reduces the intensity of the sensing signal of the photoelectric sensing device and/or increases the noise generated, thereby reducing the signal-to-noise ratio (SNR) of the photoelectric sensing device.

### SUMMARY

A photoelectric sensing device with improved signal-to-noise ratio is provided in the disclosure.

According to an embodiment of the disclosure, a photoelectric sensing device includes a substrate, a first pixel structure, a second pixel structure, and a first bus line. The first pixel structure is disposed on the substrate and includes a first photoelectric sensing component, in which the first photoelectric sensing component has a first semiconductor layer. The second pixel structure is disposed on the substrate and includes a second photoelectric sensing component, in which the second photoelectric sensing component has a second semiconductor layer. The first bus line is disposed on the substrate and is located between the first semiconductor layer and the second semiconductor layer, in which the first bus line is electrically connected to the first pixel structure and the second pixel structure.

Based on the above, the photoelectric sensing device of the disclosure includes a first bus line electrically connected to the first pixel structure and the second pixel structure. The signals to be provided and/or received by the first pixel structure and the second pixel structure all come from the first bus line, so that the number of signal lines provided in the photoelectric sensing device may be reduced. Therefore, the area of the photoelectric sensing region of the pixel structure may be increased to increase the signal intensity sensed by the photoelectric sensing device, and the area of the circuit layout region of the pixel structure may also be increased to reduce noise in the photoelectric sensing device. Therefore, the signal-to-noise ratio of the photoelectric sensing device of the disclosure may be improved.

### BRIEF DESCRIPTION OF THE DRAWINGS

FIG. 1A is a partial top schematic diagram of the photoelectric sensing device of the first embodiment of the disclosure.

FIG. 1B is an equivalent circuit diagram of the photoelectric sensing device of the first embodiment of the disclosure.

FIG. 2A is a partial top schematic diagram of the photoelectric sensing device of the second embodiment of the disclosure.

FIG. 2B is an equivalent circuit diagram of the photoelectric sensing device of the second embodiment of the disclosure.

FIG. 3A is a partial top schematic diagram of the photoelectric sensing device of the third embodiment of the disclosure.

FIG. 3B is an equivalent circuit diagram of the photoelectric sensing device of the third embodiment of the disclosure.

FIG. 4A is a partial top schematic diagram of the photoelectric sensing device of the fourth embodiment of the disclosure.

FIG. 4B is an equivalent circuit diagram of the photoelectric sensing device of the fourth embodiment of the disclosure.

FIG. 5A is a partial top schematic diagram of the photoelectric sensing device of the fifth embodiment of the disclosure.

FIG. 5B is an equivalent circuit diagram of the photoelectric sensing device of the fifth embodiment of the disclosure.

FIG. 6 is a partial top schematic diagram of the photoelectric sensing device of the sixth embodiment of the disclosure.

### DETAILED DESCRIPTION OF DISCLOSED EMBODIMENTS

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

Certain terms may be used throughout the disclosure and the appended patent claims to refer to specific elements. It should be understood by those skilled in the art that electronic device manufacturers may refer to the same elements by different names. The disclosure does not intend to distinguish between elements that have the same function but have different names. In the following description and patent claims, words such as “comprising”, “including”, and “having” are open-ended words, so they should be interpreted as meaning “including but not limited to . . . ”. Accordingly, when the terms “comprising”, “including”, and/or “having” are used in the description of this disclosure, they designate the presence of the corresponding feature, region, step, operation and/or component, but do not exclude the presence of one or more of a corresponding feature, region, step, operation, and/or component.

In the disclosure, wordings used to indicate directions, such as “up,” “down,” “front,” “back,” “left,” and “right,” merely refer to directions in the accompanying drawings. Therefore, the directional wordings are used to illustrate rather than limit the disclosure. In the accompanying drawings, the drawings illustrate the general features of the methods, structures, and/or materials used in the particular embodiments. However, the drawings shall not be interpreted as defining or limiting the scope or nature covered by the embodiments. For example, the relative sizes, thicknesses, and locations of the layers, regions, and/or structures may be reduced or enlarged for clarity.

When a corresponding component (e.g., a film layer or region) is referred to as being “on” another component, it may be directly on the other component or other components may be present therebetween. On the other hand, when a component is referred to as being “directly on” another member, there are no components in between. Additionally, when a component is referred to as being “on” another component, the two are in a top-down relationship when viewed from above, and the component may be above or below the other component, depending on the orientation of the device.

The terms “about”, “equal to”, “equal” or “same”, “substantially” or “generally” are interpreted as within 20% of a given value or range, or interpreted as within 10%, 5%, 3%, 2%, 1%, or 0.5% of the given value or range.

The terms such as “first”, “second”, etc. used in the description and the patent claims are used to modify elements, which do not imply and represent that the (or these) elements have any previous ordinal numbers, and also does not represent the order of a certain element and another element, or the order of the manufacturing method. The use of these ordinal numbers is to only clearly distinguish an element with a certain name from another element with the same name. The same terms may not be used in the patent claims and the description, and accordingly, the first component in the description may be the second component in the patent claims.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

The electrical connection or coupling described in the disclosure may refer to direct connection or indirect connection. In the case of a direct connection, the end points of two elements on a circuit directly connect to each other, or connect to each other through a conductive wire. In the case of indirect connection, a switch, a diode, a capacitor, an inductor, other suitable elements, or a combination thereof, but not limited therein, is between the end points of two elements on a circuit.

In the disclosure, the thickness, length, and width may be measured by adopting a measurement method such as an optical microscope (OM), and the thickness may be measured from a cross-sectional image in an electronic microscope, but not limited thereto. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80 degrees and 100 degrees; if the first direction is parallel to the second direction, an angle between the first direction and the second direction may be between 0 degrees and 10 degrees.

The electronic device of this disclosure may include, but is not limited to, detection device, display device, antenna device (e.g., liquid crystal antenna), light-emitting touch control device, splicing device, device having other suitable functions, or device having a combination of the aforementioned functions. The electronic device includes, but is not limited to, a rollable or flexible electronic device. The electronic device may, for example, comprise liquid crystal, light emitting diode (LED), quantum dot (QD), fluorescence, phosphor, other suitable materials or the combination thereof. The light emitting diode may for example include an organic light emitting diode (OLED), a micro/mini light emitting diode (micro-LED, mini-LED) or a quantum dot light emitting diode (QLED, QDLED), but not limited thereto. The electronic device may include electronic elements. Electronic elements may include passive and active elements, such as capacitors, resistors, inductors, diodes, transistors, and the like. The diode may include a light emitting diode or a photodiode. The light emitting diode may include, for example, an organic light-emitting diode (OLED), a mini light-emitting diode (mini LED), a micro light-emitting diode (micro LED), or a quantum dot light-emitting diode (quantum dot, QD, such as QLED, QDLED), or other suitable materials, or any arrangement and combination of the materials thereof, but not limited thereto. It should be noted that, the electronic device may be any arrangement and combination of the foregoing, but not limited thereto. In addition, the shape of the electronic device may be rectangular, circular, polygonal, a shape with curved edges, or other suitable shapes. The electronic device may have peripheral systems such as a driving system, a control system, a light source system, a shelf system, etc. to support a display device or a spliced device. It should be noted that, the electronic device may be any arrangement and combination of the foregoing, but not limited thereto. The electronic device may include multiple components, at least two of which may be assembled to form a composite object. Hereinafter, the detecting device is used as the electronic device to illustrate this disclosure, but this disclosure is not limited thereto.

Exemplary embodiments of this disclosure are exemplified below, the same reference numerals in the drawings and the descriptions indicate the same or similar parts.

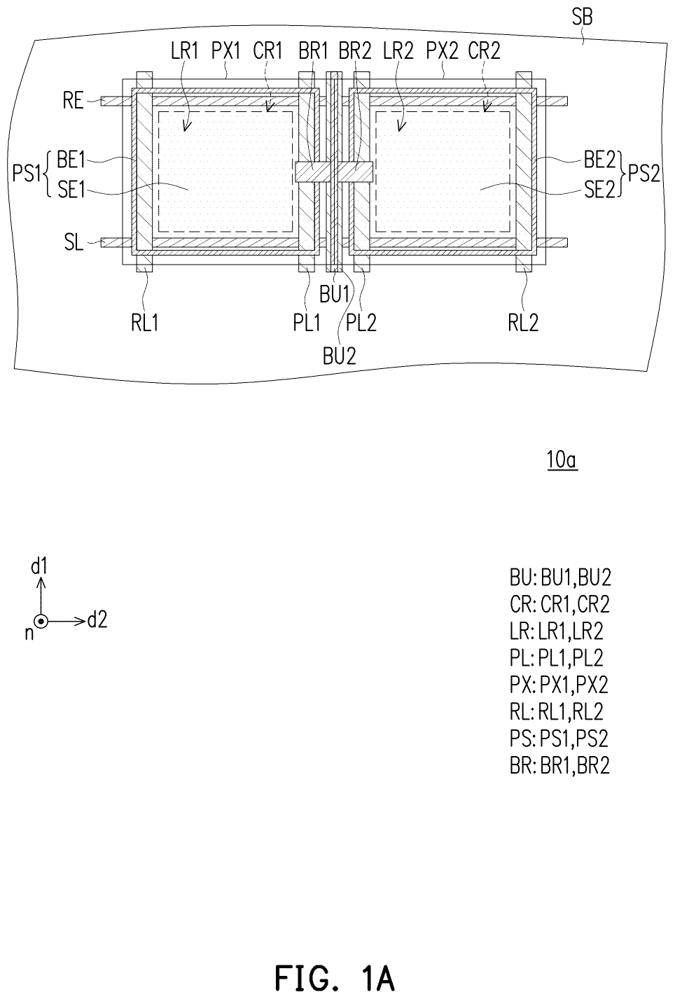

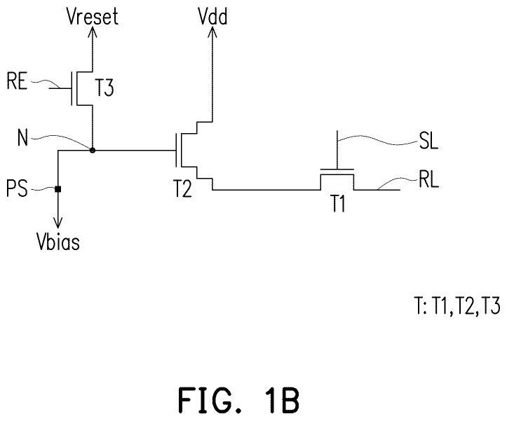

FIG. 1A is a partial top schematic diagram of the photoelectric sensing device of the first embodiment of the disclosure, and FIG. 1B is an equivalent circuit diagram of the photoelectric sensing device of the first embodiment of the disclosure.

Referring to FIG. 1A, the photoelectric sensing device 10a of this embodiment includes a substrate SB, a pixel structure PX, a bus line BU, a selection line SL, a read line RL, a power line PL and a reset line RE.

The material of the substrate SB may include, for example, a hard material, a soft material, or a combination thereof. For example, the material of the substrate SB may include quartz, sapphire, polymethyl methacrylate (PMMA), polycarbonate (PC), polyimide (PI), polyethylene terephthalate (PET), or other suitable materials, or a combination thereof, the disclosure is not limited thereto.

The pixel structure PX is, for example, disposed on the substrate SB. In this embodiment, the pixel structure PX includes a first pixel structure PX1 and a second pixel structure PX2. The first pixel structure PX1 includes a first semiconductor layer SE1, and the second pixel structure PX2 includes a second semiconductor layer SE2, as shown in FIG. 1A. From another perspective, in this embodiment, the pixel structure PX includes a photoelectric sensing component PS and a transistor T, as shown in FIG. 1B. Based on this, the pixel structure PX has, for example, a photoelectric sensing region LR and a circuit layout region CR. The photoelectric sensing region LR is, for example, defined as the region where the semiconductor layer (e.g., the first semiconductor layer SE1 and the second semiconductor layer SE2) of the photoelectric sensing component PS is not blocked by a light shielding layer (in the direction of the normal direction n of the substrate SB), and the circuit layout region CR is the region in the pixel structure PX where circuit layout may be designed, but the disclosure is not limited thereto. In this embodiment, the first pixel structure PX1 may include a first photoelectric sensing region LR1 and a first circuit layout region CR1, and the second pixel structure PX2 may include a second photoelectric sensing region LR2 and a second circuit layout region CR2.

The photoelectric sensing component PS is, for example, disposed on the substrate SB and coupled to the transistor T. In this embodiment, the photoelectric sensing component PS includes a first photoelectric sensing component PS1 located in the first pixel structure PX1 and a second photoelectric sensing component PS2 located in the second pixel structure PX2, but the disclosure is not limited thereto. The first photoelectric sensing component PS1 may, for example, include a lower electrode BE1, an upper electrode (not shown), and a first semiconductor layer SE1, and the second photoelectric sensing component PS2 may, for example, include a lower electrode BE2, an upper electrode (not shown), and a second semiconductor layer SE2. The first semiconductor layer SE1 is disposed between the lower electrode BE1 and the upper electrode in the normal direction n of the substrate SB, and the second semiconductor layer SE2 is disposed between the lower electrode BE2 and the upper electrode in the normal direction n of the substrate SB. The materials of the lower electrode BE1, the lower electrode BE2, and the upper electrode include, for example, transparent conductive materials, which may be, for example, indium tin oxide (ITO), but the disclosure is not limited thereto. The photoelectric sensing component PS may be, for example, coupled to the transistor T through the lower electrode BE, and may be, for example, coupled to the bus line BU, which will be introduced subsequently, through the upper electrode. The materials of the first semiconductor layer SE1 and the second semiconductor layer SE2 include, for example, amorphous silicon, but the disclosure is not limited thereto. In other embodiments, the first semiconductor layer SE1 and the second semiconductor layer SE2 may include single crystal material or polycrystalline material. In some embodiments, the first semiconductor layer SE1 and the second semiconductor layer SE2 may include a first layer (not shown), an intrinsic layer (not shown), and a second layer (not shown). For example, the first layer, the intrinsic layer, and the second layer are stacked in this order in the normal direction n of the substrate SB, but the disclosure is not limited thereto.

The transistor T is, for example, disposed on the substrate SB and coupled to the photoelectric sensing component PS. The transistor T may be, for example, a top gate thin film transistor or other thin film transistors well known to those skilled in the art, and the disclosure is not limited thereto. For example, the transistor T may include a gate (not shown), a source (not shown), a drain (not shown), and a semiconductor (not shown). The gate at least partially overlaps the semiconductor in the normal direction n of the substrate SB, and the source and the drain are separated from each other and electrically connected to the semiconductor. In this embodiment, the transistor T includes a selection transistor T1, a driving transistor T2, and a reset transistor T3, but the disclosure is not limited thereto.

The bus line BU is, for example, disposed on the substrate SB and is electrically connected to the pixel structure PX. In this embodiment, the bus line BU is electrically connected to the first pixel structure PX1 and the second pixel structure PX2 to provide and/or receive corresponding signals of the first pixel structure PX1 and the second pixel structure PX2. For example, as shown in FIG. 1A, the bus line BU may include a first bus line BU1 and a second bus line BU2. The first bus line BU1 may be a bias line for providing a bias signal, and the second bus line BU2 may be a reset line for providing a reset signal, but the disclosure is not limited thereto. For example, the first bus line BU1 at least partially overlaps the second bus line BU2 in the normal direction n of the substrate SB. In this embodiment, the first bus line BU1 overlaps the second bus line BU2 in the normal direction n of the substrate SB. Based on this, in this embodiment, the signals to be provided and/or received by the first pixel structure PX1 and the second pixel structure PX2 all come from one bus line BU, so that the number of signal lines provided in the photoelectric sensing device 10a may be reduced. Therefore, the area of the first photoelectric sensing region LR1 of the first pixel structure PX1 and the area of the second photoelectric sensing region LR2 of the second pixel structure PX2 may be respectively increased, thereby improving the signal intensity sensed by the photoelectric sensing device 10a. Furthermore, the configuration of integrating at least two signal lines into one bus line BU may also respectively increase the area of the first circuit layout region CR1 of the first pixel structure PX1 and the area of the second circuit layout region CR2 of the second pixel structure PX2, so that the circuit design in the first circuit layout region CR1 and the second circuit layout region CR2 may be more flexible, thereby reducing the noise generated in the photoelectric sensing device 10a. Based on this, the signal-to-noise ratio (SNR) of the photoelectric sensing device 10a of this embodiment may be improved.

In some embodiments, the photoelectric sensing device 10a may further include a bridge electrode BR, in which the bridge electrode BR is configured to electrically connect the bus line BU to the corresponding pixel structure PX. Specifically, in this embodiment, the first bus line BU1 may be electrically connected to the first pixel structure PX1 through the first bridge electrode BR1, and may be electrically connected to the second pixel structure PX2 through the second bridge electrode BR2. In addition, although not shown in FIG. 1A, the second bus line BU2 may also be electrically connected to the corresponding pixel structure PX through the bridge electrode BR. It is worth noting that although this embodiment shows that the bridge electrode BR and the first bus line BU1 belong to the same layer, the disclosure is not limited thereto. That is, the bridge electrode BR and the first bus line BU1 may belong to different layers.

The bus line BU extends, for example, in the first direction d1, and is, for example, located between the first semiconductor layer SE1 in the first photoelectric sensing component PS1 and the second semiconductor layer SE2 in the second photoelectric sensing component PS2. The first direction d1 may be, for example, orthogonal to the normal direction n of the substrate SB, but the disclosure is not limited thereto. In some embodiments, the bus line BU does not overlap the first semiconductor layer SE1 and the second semiconductor layer SE2 in the normal direction n of the substrate SB. Based on this, by preventing the bus line BU from overlapping the first semiconductor layer SE1 in the first photoelectric sensing component PS1 and the second semiconductor layer SE2 in the second photoelectric sensing component PS2 in the normal direction n of the substrate SB, the photoelectric sensing area of the pixel structure PX in the normal direction n of the substrate SB may be increased to increase the fill factor (FF) of the photoelectric sensing device 10a, thereby improving the photoelectric conversion efficiency of the photoelectric sensing device 10a.

The selection line SL is, for example, disposed on the substrate SB and is coupled to, for example, a control terminal of the selection transistor T1. The selection line SL may be configured to, for example, provide a selection signal to the selection transistor T1 to turn it on. In some embodiments, the selection line SL extends toward the second direction d2, in which the second direction d2 may be orthogonal to the first direction d1 and the normal direction n of the substrate SB, but the disclosure is not limited thereto.

The read line RL is, for example, disposed on the substrate SB and is coupled to, for example, the first terminal of the selection transistor T1. The read line RL may be configured to, for example, receive a signal (sensing current) generated from the photoelectric sensing component PS when the selection transistor T1 is turned on, and the read line RL may transmit this sensing current to the processing circuit (not shown). The processing circuit can, for example, convert the sensing current into a sensing voltage and determine the intensity of light received by the photoelectric sensing device 10a, but the disclosure is not limited thereto. In some embodiments, the read line RL extends toward the first direction d1, but the disclosure is not limited thereto. In this embodiment, the read line RL includes a read line RL1 and a read line RL2. The read line RL1 is electrically connected to the first pixel structure PX1, and the read line RL2 is electrically connected to the second pixel structure PX2, but the disclosure is not limited thereto.

The power line PL is, for example, disposed on the substrate SB and is coupled to, for example, the second terminal of the drive transistor T2. The power line PL may be configured to, for example, provide a high voltage (e.g., power voltage Vdd) to the driving transistor T2 so that the driving transistor T2 may output current when it is turned on. In some embodiments, the power line PL extends toward the first direction d1, but the disclosure is not limited thereto. In this embodiment, the power line PL includes a power line PL1 and a power line PL2. The power line PL1 is electrically connected to the first pixel structure PX1, and the power line PL2 is electrically connected to the second pixel structure PX2, but the disclosure is not limited thereto.

The reset line RE is, for example, disposed on the substrate SB and is coupled to, for example, a control terminal of the reset transistor T3. The reset line RE may be configured to, for example, provide a reset signal to the reset transistor T3 to turn it on, for example, to modulate the voltage of the control terminal of the driving transistor T2. In some embodiments, the reset line RE extends toward the second direction d2, but the disclosure is not limited thereto.

In this embodiment, the first pixel structure PX1 and the second pixel structure PX2 may be disposed to mirror each other on two sides of the bus line BU. For example, the first pixel structure PX1 and the second pixel structure PX2 may be arranged along the second direction d2, and the photoelectric sensing component PS and the transistor T included in the first pixel structure PX1 and the second pixel structure PX2 respectively may be disposed to mirror each other on two sides of the bus line BU, but the disclosure is not limited thereto. In some embodiments, the read line RL1 and the read line RL2 may be disposed to mirror each other on two sides of the bus line BU, and the power line PL1 and the power line PL2 may be disposed to mirror each other on two sides of the bus line BU, but the disclosure is not limited thereto.

In the circuit diagram shown in FIG. 1B, the components in the photoelectric sensing device 10a have the following coupling relationships, but the disclosure is not limited thereto.

The control terminal of the selection transistor T1 is, for example, coupled to the selection line SL. The first terminal of the selection transistor T1 is, for example, coupled to the read line RL. The second terminal of the selection transistor T1 is, for example, coupled to the first terminal of the driving transistor T2. The control terminal of the driving transistor T2 is, for example, coupled to the node N. The second terminal of the driving transistor T2 is, for example, coupled to the power line PL that provides the power voltage Vdd. The control terminal of the reset transistor T3 is, for example, coupled to the reset line RE. The first terminal of the reset transistor T3 is, for example, coupled to the node N. The second terminal of the reset transistor T3 is, for example, coupled to the second bus line BU2 that provides the reset voltage Vreset. The cathode terminal (lower electrode BE) of the photoelectric sensing component PS may be, for example, coupled to the node N. The anode terminal (upper electrode) of the photoelectric sensing component PS may be, for example, coupled to the first bus line BU1 that provides the bias voltage Vbias, but the disclosure is not limited thereto. In other embodiments, the cathode terminal (upper electrode) of the photoelectric sensing component PS may be, for example, coupled to the node N, and the anode terminal (lower electrode BE) of the photoelectric sensing component PS may be, for example, coupled to the first bus line BU1 that provides the bias voltage Vbias.

In this embodiment, the photoelectric sensing device 10a may be operated through the following steps, but the disclosure is not limited thereto.

First, a reset step is performed, which provides a signal to the control terminal of the reset transistor T3 to turn on the reset transistor T3 by using the reset line RE, so that the voltage of the node N is reset or modulated to the reset voltage Vreset.

Next, an illumination step is performed, which turns off the reset transistor T3 and causes the photoelectric sensing component PS to be irradiated with light for a specific time. The photoelectric sensing component PS may receive the light and generate a signal, so that the voltage of the node N is changed. The voltage of the node N may be affected, for example, by the intensity and/or time of the light irradiating the photoelectric sensing component PS.

Then, a reading step is performed. After the photoelectric sensing component PS is irradiated with light for a specific period of time, a signal is provided to the control terminal of the selection transistor T1 to turn on the selection transistor T1 by using the selection line SL. Therefore, the driving transistor T2 with the power supply voltage Vdd applied to the second terminal may output a current, and it may be provided to the read line RL via the turned-on selection transistor T1. It is worth noting that the current output by the driving transistor T2 is affected by, for example, the voltage of the node N, that is, it is affected by the intensity and/or time of the light irradiating the photoelectric sensing component PS. Subsequently, the sensing current may be converted into a sensing voltage and the intensity of the light received by the photoelectric sensing device 10a may be determined, for example, through a processing circuit coupled to the read line RL, but the disclosure is not limited thereto.

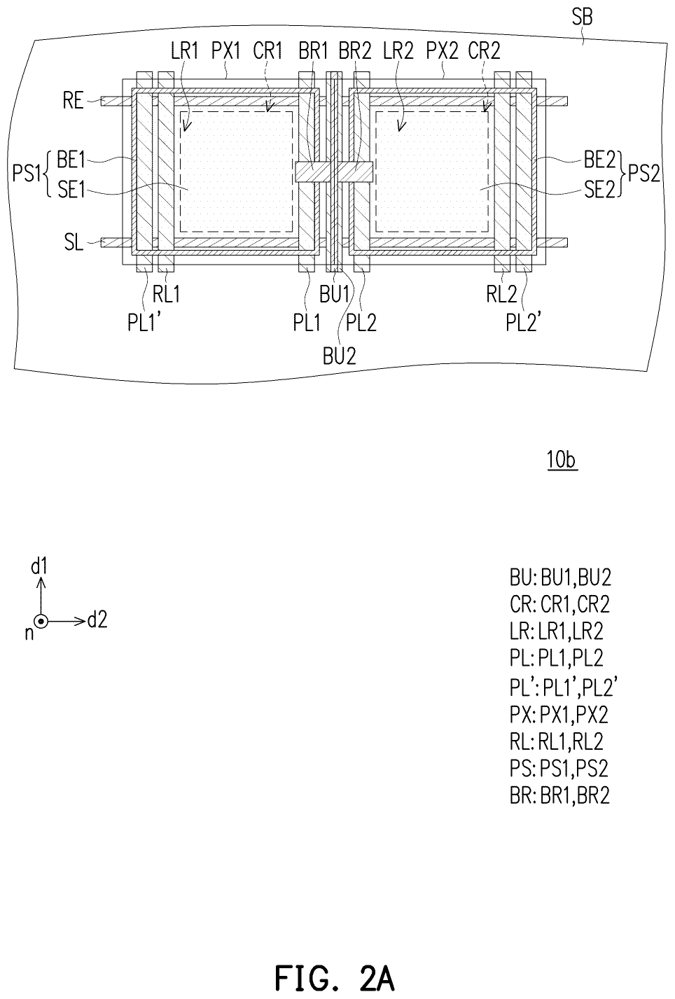

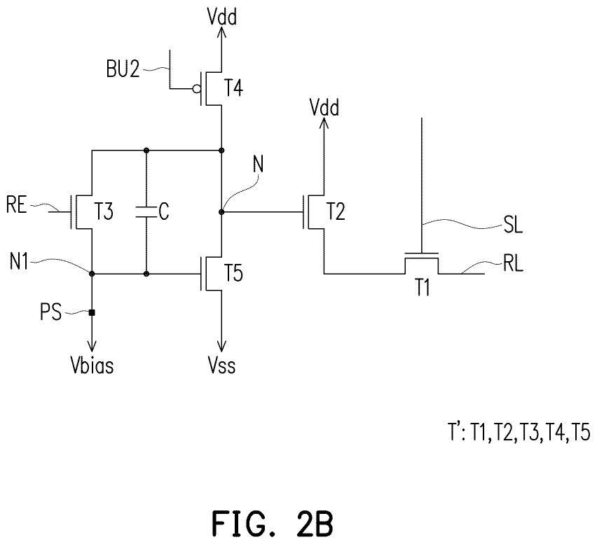

FIG. 2A is a partial top schematic diagram of the photoelectric sensing device of the second embodiment of the disclosure, and FIG. 2B is an equivalent circuit diagram of the photoelectric sensing device of the second embodiment of the disclosure. It is noted that the embodiment of FIG. 2A and FIG. 2B may respectively use the reference numerals and a part of the contents of the embodiment of FIG. 1A and FIG. 1B, and the same or similar reference numerals are used to denote the same or similar elements, and the description of the same technical content is omitted.

Referring to FIG. 2A and FIG. 2B at the same time, the main differences between the photoelectric sensing device 10b of this embodiment and the aforementioned photoelectric sensing device 10a are: (1) the photoelectric sensing device 10b also includes a power line PL′ and a capacitor C, and the transistor T′ also includes a load transistor T4 and a load transistor T5; (2) the second bus line BU2 is an active load line for providing a load signal.

The power line PL′ is, for example, disposed on the substrate SB and is, for example, coupled to the first terminal of the driving transistor T2. The power line PL′ may be configured to, for example, provide a low voltage (e.g., reference voltage Vss) to the load transistor T5. In some embodiments, the power line PL′ extends toward the first direction d1, but the disclosure is not limited thereto. In this embodiment, the power line PL′ includes a power line PL1′ and a power line PL2′. The power line PL1′ is electrically connected to the first pixel structure PX1, and the power line PL2′ is electrically connected to the second pixel structure PX2, but the disclosure is not limited thereto. In addition, in some embodiments, the power line PL1′ and the power line PL2′ may be disposed to mirror each other on two sides of the bus line BU, but the disclosure is not limited thereto.

In this embodiment, the second bus line BU2 is a load signal line configured to provide a load signal, and is coupled to the control terminal of the load transistor T4. The load transistor T4 is, for example, an active load, and its resistance value affects the voltage of the node N.

In the circuit diagram shown in FIG. 2B, the components in the photoelectric sensing device 10b have the following coupling relationships, but the disclosure is not limited thereto.

The control terminal of the selection transistor T1 is, for example, coupled to the selection line SL. The first terminal of the selection transistor T1 is, for example, coupled to the read line RL. The second terminal of the selection transistor T1 is, for example, coupled to the first terminal of the driving transistor T2. The control terminal of the driving transistor T2 is, for example, coupled to the node N. The second terminal of the driving transistor T2 is, for example, coupled to the power line PL that provides the power voltage Vdd. The control terminal of the reset transistor T3 is, for example, coupled to the reset line RE. The first terminal of the reset transistor T3 is, for example, coupled to the node N1. The second terminal of the reset transistor T3 is, for example, coupled to the node N. The cathode terminal (lower electrode BE) of the photoelectric sensing component PS is, for example, coupled to the node N1. The anode terminal (upper electrode) of the photoelectric sensing component PS is, for example, coupled to the first bus line BU1 that provides the bias voltage Vbias. The first terminal and the second terminal of the capacitor C are, for example, electrically connected to the first terminal and the second terminal of the reset transistor T3 respectively. The control terminal of the load transistor T4 is, for example, coupled to the second bus line BU2 that provides the load signal. The first terminal of the load transistor T4 is, for example, coupled to the node N. The second terminal of the load transistor T4 is, for example, coupled to the power line PL that provides the power voltage Vdd. The control terminal of the load transistor T5 is, for example, coupled to the node N1. The first terminal of the load transistor T5 is, for example, coupled to the power line PL′ that provides the reference voltage Vss. The second terminal of the load transistor T5 is, for example, coupled to the node N.

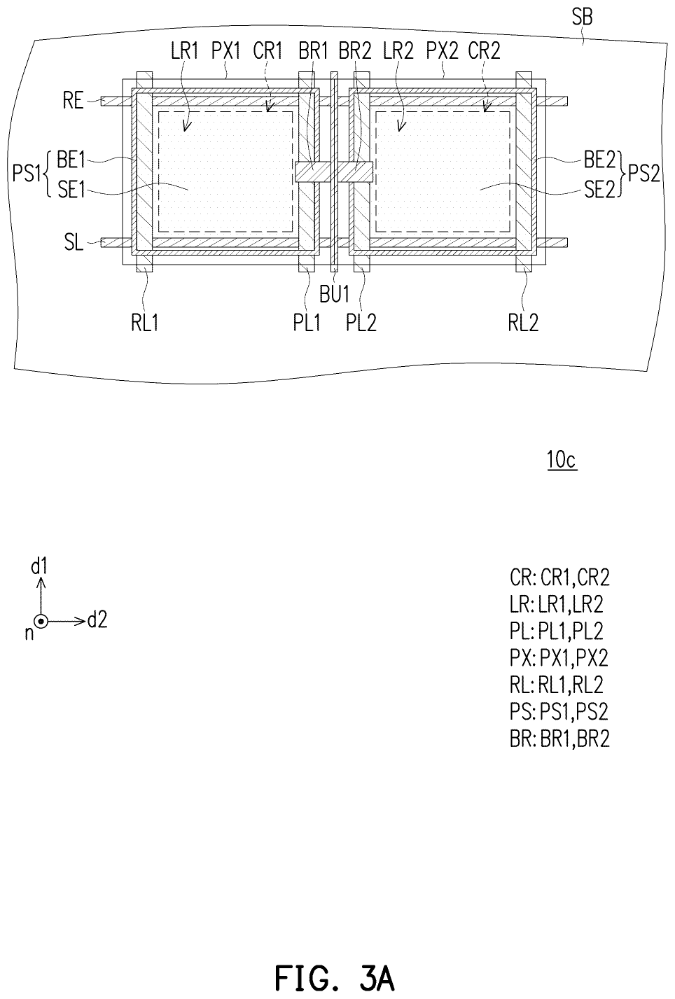

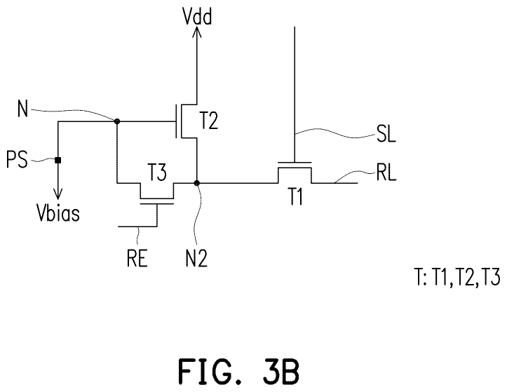

FIG. 3A is a partial top schematic diagram of the photoelectric sensing device of the third embodiment of the disclosure, and FIG. 3B is an equivalent circuit diagram of the photoelectric sensing device of the third embodiment of the disclosure. It is noted that the embodiment of FIG. 3A and FIG. 3B may respectively use the reference numerals and a part of the contents of the embodiment of FIG. 1A and FIG. 1B, and the same or similar reference numerals are used to denote the same or similar elements, and the description of the same technical content is omitted.

Referring to FIG. 3A and FIG. 3B at the same time, the main difference between the photoelectronic sensing device 10c of this embodiment and the aforementioned photoelectronic sensing device 10a is that the photoelectric sensing device 10c does not include the second bus line BU2.

In the circuit diagram shown in FIG. 3B, the components in the photoelectric sensing device 10c have the following coupling relationships, but the disclosure is not limited thereto.

The control terminal of the selection transistor T1 is, for example, coupled to the selection line SL. The first terminal of the selection transistor T1 is, for example, coupled to the read line RL. The second terminal of the selection transistor T1 is, for example, coupled to the node N2. The control terminal of the driving transistor T2 is, for example, coupled to the node N. The first terminal of the driving transistor T2 is, for example, coupled to the node N2. The second terminal of the driving transistor T2 is, for example, coupled to the power line PL that provides the power voltage Vdd. The control terminal of the reset transistor T3 is, for example, coupled to the reset line RE. The first terminal of the reset transistor T3 is, for example, coupled to the node N2. The second terminal of the reset transistor T3 is, for example, coupled to the node N. The cathode terminal (lower electrode BE) of the photoelectric sensing component PS is, for example, coupled to the node N. The anode terminal (upper electrode) of the photoelectric sensing component PS is, for example, coupled to the first bus line BU1 that provides the bias voltage Vbias.

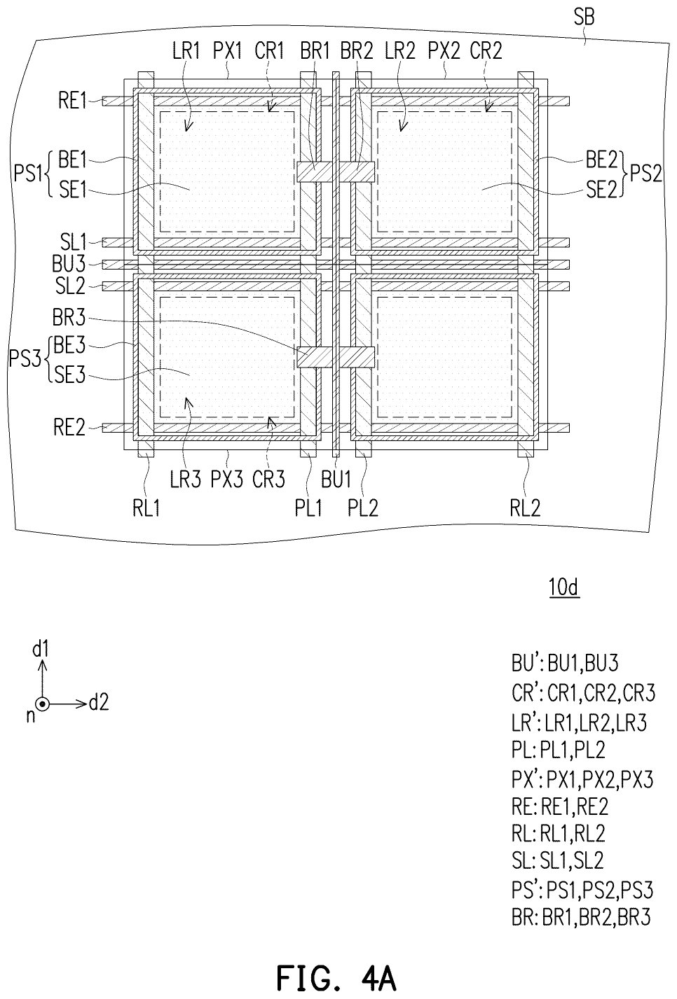

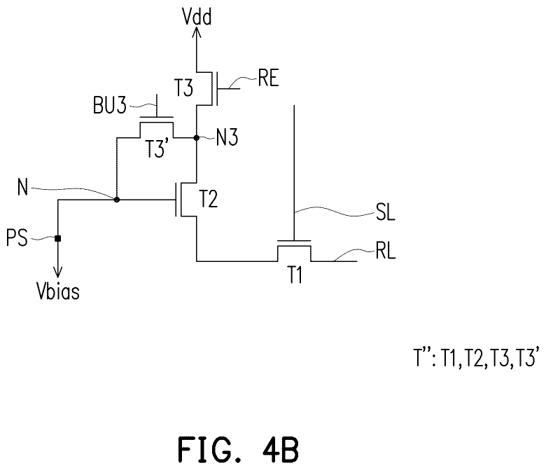

FIG. 4A is a partial top schematic diagram of the photoelectric sensing device of the fourth embodiment of the disclosure, and FIG. 4B is an equivalent circuit diagram of the photoelectric sensing device of the fourth embodiment of the disclosure. It is noted that the embodiment of FIG. 4A and FIG. 4B may respectively use the reference numerals and a part of the contents of the embodiment of FIG. 3A and FIG. 3B, and the same or similar reference numerals are used to denote the same or similar elements, and the description of the same technical content is omitted.

Referring to FIG. 4A and FIG. 4B at the same time, the main differences between the photoelectric sensing device 10d of this embodiment and the aforementioned photoelectric sensing device 10c are that: the pixel structure PX′ also includes a third pixel structure PX3 (therefore, the photoelectric sensing region LR′ also includes a third photoelectric sensing region LR3, and the circuit layout region CR′ also includes a third circuit layout region CR3; or, the photoelectric sensing component PS′ also includes a third photoelectric sensing component PS3, in which the third photoelectric sensing component PS3 includes a third semiconductor layer SE3), the bus line BU′ also includes a third bus line BU3, and the transistor T also includes a reset transistor T3′.

In this embodiment, the third bus line BU3 is electrically connected to the third pixel structure PX3 to provide and/or receive corresponding signals of the third pixel structure PX3. The third bus line BU3 extends, for example, in the second direction d2, and is, for example, located between the first semiconductor layer SE1 in the first photoelectric sensing component PS1 and the third semiconductor layer SE3 in the third photoelectric sensing component PS3. In this embodiment, the third bus line BU3 may be a reset switch control signal line (global reset line) configured to provide a reset switch control signal, but the disclosure is not limited thereto. In detail, the third bus line BU3 is, for example, coupled to the control terminal of the reset transistor T3′. The third bus line BU3 may be configured to, for example, provide a reset switch control signal to the reset transistor T3′ to turn it on, for example, to modulate the voltage of the control terminal of the driving transistor T2.

In this embodiment, the first pixel structure PX1 and the third pixel structure PX3 may be disposed to mirror each other on two sides of the third bus line BU3. For example, the first pixel structure PX1 and the third pixel structure PX3 may be arranged along the first direction d1, and the photoelectric sensing components (the first photoelectric sensing component PS1 and the third photoelectric sensing component PS3) and transistors T included in the first pixel structure PX1 and the third pixel structure PX3 respectively may be disposed to mirror each other on two sides of the third bus line BU3, but the disclosure is not limited thereto.

In this embodiment, the selection line SL includes a selection line SL1 and a selection line SL2. The selection line SL1 and the selection line SL2 may be disposed to mirror each other on two sides of the third bus line BU3. In addition, in this embodiment, the reset line RE includes a reset line RE1 and a reset line RE2. The reset line RE1 and the reset line RE2 may be disposed to mirror each other on two sides of the third bus line BU3.

In addition, in this embodiment, the first bus line BU1 may be electrically connected to the third pixel structure PX3 through the third bridge electrode BR3 of the bridge electrode BR to provide and/or receive corresponding signals of the third pixel structure PX3.

In the circuit diagram shown in FIG. 4B, the components in the photoelectric sensing device 10d have the following coupling relationships, but the disclosure is not limited thereto.

The control terminal of the selection transistor T1 is, for example, coupled to the selection line SL. The first terminal of the selection transistor T1 is, for example, coupled to the read line RL. The second terminal of the selection transistor T1 is, for example, coupled to the first terminal of the driving transistor T2. The control terminal of the driving transistor T2 is, for example, coupled to the node N. The second terminal of the driving transistor T2 is, for example, coupled to the node N3. The control terminal of the reset transistor T3 is, for example, coupled to the reset line RE. The first terminal of the reset transistor T3 is, for example, coupled to the node N3. The second terminal of the reset transistor T3 is, for example, coupled to the power line PL that provides the power voltage Vdd. The control terminal of the reset switch control transistor T3′ is coupled to the third bus line BU3. The first terminal of the reset switch control transistor T3′ is, for example, coupled to the node N3. The second terminal of the reset switch control transistor T3′ is, for example, coupled to the node N. The cathode terminal (lower electrode BE) of the photoelectric sensing component PS is, for example, coupled to the node N. The anode end (upper electrode) of the photoelectric sensing component PS is, for example, coupled to the first bus line BU1 that provides the bias voltage Vbias.

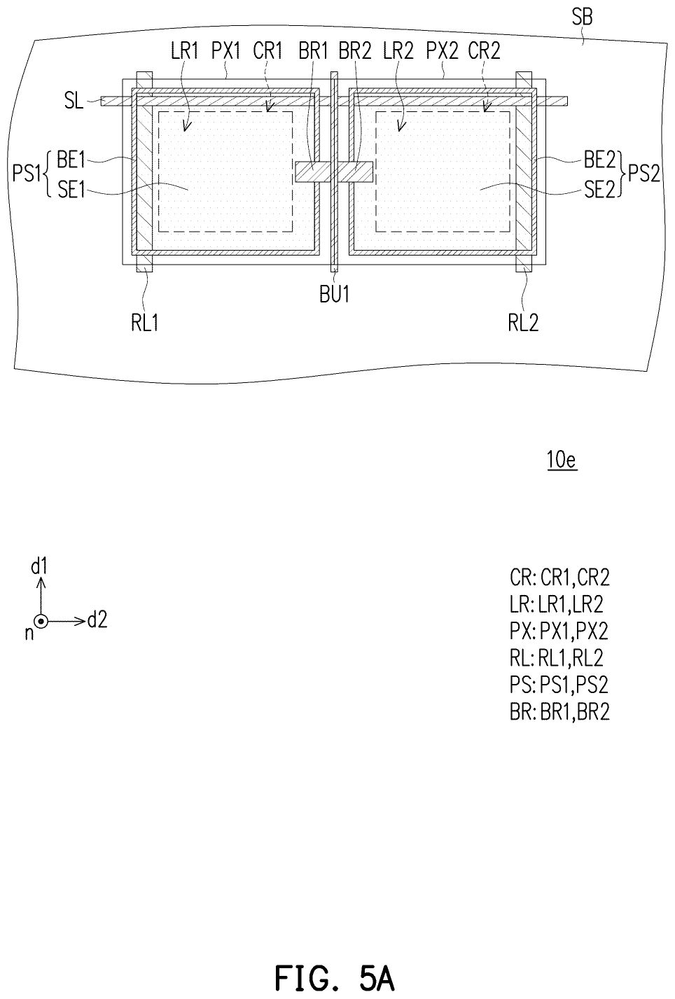

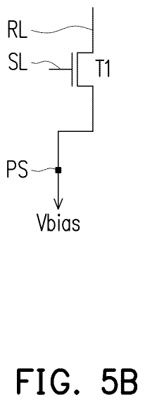

FIG. 5A is a partial top schematic diagram of the photoelectric sensing device of the fifth embodiment of the disclosure, and FIG. 5B is an equivalent circuit diagram of the photoelectric sensing device of the fifth embodiment of the disclosure. It is noted that the embodiment of FIG. 5A and FIG. 5B may respectively use the reference numerals and a part of the contents of the embodiment of FIG. 1A and FIG. 1B, and the same or similar reference numerals are used to denote the same or similar elements, and the description of the same technical content is omitted.

Referring to FIG. 5A and FIG. 5B at the same time, the main difference between the photoelectronic sensing device 10e of this embodiment and the aforementioned photoelectronic sensing device 10a is that: the photoelectric sensing device 10e does not include the second bus line BU2 and the power line PL, and the transistor T does not include the driving transistor T2 and the reset transistor T3.

In the circuit diagram shown in FIG. 5B, the components in the photoelectric sensing device 10e have the following coupling relationships, but the disclosure is not limited thereto.

The control terminal of the selection transistor T1 is, for example, coupled to the selection line SL. The first terminal of the selection transistor T1 is, for example, coupled to the read line RL. The second terminal of the selection transistor T1 is, for example, coupled to the cathode terminal (lower electrode BE) of the photoelectric sensing component PS. The anode end (upper electrode) of the photoelectric sensing component PS is, for example, coupled to the first bus line BU1 that provides the bias voltage Vbias.

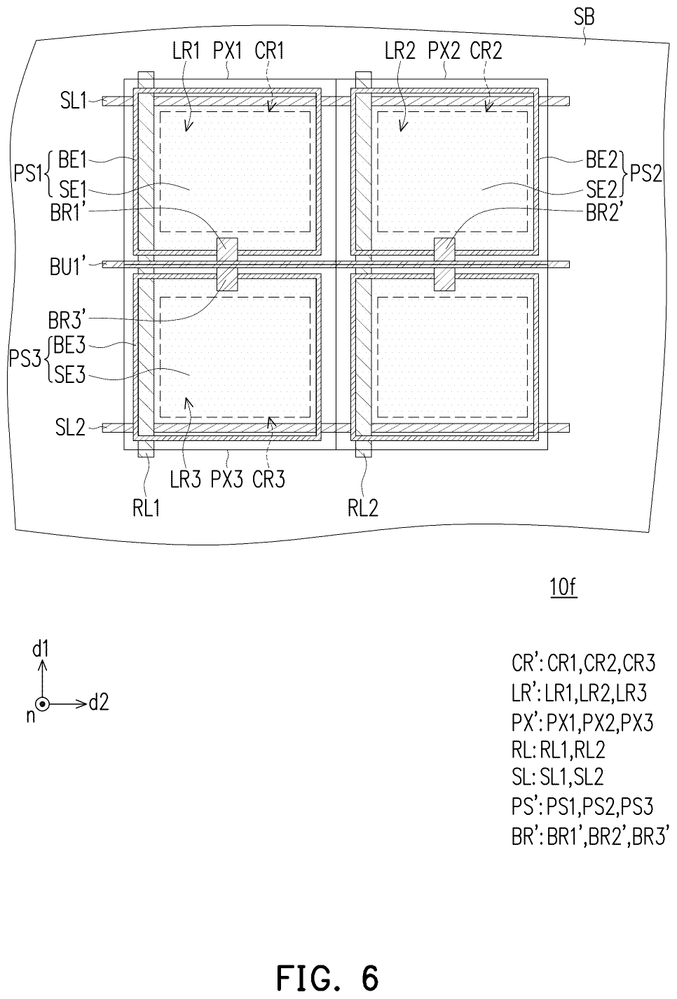

FIG. 6 is a partial top schematic diagram of the photoelectric sensing device of the sixth embodiment of the disclosure. It is noted that the embodiment of FIG. 6 may use the reference numerals and a part of the contents of the embodiment of FIG. 5A, and the same or similar reference numerals are used to denote the same or similar elements, and the description of the same technical content is omitted.

Referring to FIG. 6, the main difference between the photoelectric sensing device 10f of this embodiment and the aforementioned photoelectric sensing device 10e is that the first bus line BU1′ extends toward the second direction d2.

In this embodiment, the first pixel structure PX1 and the third pixel structure PX3 may be disposed to mirror each other on two sides of the first bus line BU1′. For example, the first pixel structure PX1 and the third pixel structure PX3 may be arranged along the first direction d1, and the photoelectric sensing component PS and the transistor T included in the first pixel structure PX1 and the third pixel structure PX3 respectively may be disposed to mirror each other on two sides of the first bus line BU1′, but the disclosure is not limited thereto. In this embodiment, the selection line SL includes a selection line SL1 and a selection line SL2. The selection line SL1 and the selection line SL2 may be disposed to mirror each other on two sides of the first bus line BU1′.

In addition, in this embodiment, the photoelectric sensing device 10f may include a bridge electrode BR′, in which the bridge electrode BR′ is configured to electrically connect the first bus line BU1′ to the corresponding pixel structure PX′. Specifically, in this embodiment, the first bus line BU1′ may be electrically connected to the first pixel structure PX1 through the first bridge electrode BR1′, may be electrically connected to the second pixel structure PX2 through the second bridge electrode BR2′, and may be electrically connected to the third pixel structure PX3 through the third bridge electrode BR3′. It is worth noting that although this embodiment shows that the bridge electrode BR′ and the first bus line BU1′ belong to the same layer, the disclosure is not limited thereto. That is, the bridge electrode BR′ and the first bus line BU1′ may belong to different layers.

It is worth noting that the coupling relationship of the components in the photoelectric sensing device 10f may be the same or similar to the coupling relationship of the components in the photoelectric sensing device 10e, but the disclosure is not limited thereto.

To sum up, in the photoelectric sensing device provided by some embodiments of the disclosure, the signals to be provided and/or received by adjacent pixel structures are all from one bus line, so that the number of signal lines provided in the photoelectric sensing device may be reduced. Therefore, the area of the photoelectric sensing region of the pixel structure may be increased to increase the signal intensity sensed by the photoelectric sensing device, and the area of the circuit layout region of the pixel structure may also be increased to reduce noise in the photoelectric sensing device. Therefore, the signal-to-noise ratio of the photoelectric sensing device provided by some embodiments of the disclosure may be improved.

Furthermore, in the photoelectric sensing device provided by other embodiments of the disclosure, by preventing the bus line from overlapping with the semiconductor layer in the photoelectric sensing component in the normal direction of the substrate, it may increase the photoelectric sensing area of the pixel structure in the normal direction of the substrate and improve the fill factor of the photoelectric sensing device, thereby improving the photoelectric conversion efficiency of the photoelectric sensing device provided by other embodiments of the disclosure.

Although the disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and their equivalents and not by the above detailed descriptions.

What is claimed is:

1. A photoelectric sensing device, consisting of:
a substrate;
a first pixel structure, disposed on the substrate and comprising a first photoelectric sensing component, wherein the first photoelectric sensing component has a first semiconductor layer;
a second pixel structure, disposed on the substrate and comprising a second photoelectric sensing component, wherein the second photoelectric sensing component has a second semiconductor layer; and
a first bus line, disposed on the substrate and located between the first semiconductor layer and the second semiconductor layer, wherein the first bus line is electrically connected to the first pixel structure and the second pixel structure.

2. The photoelectric sensing device according to claim 1, wherein the first pixel structure and the second pixel structure are disposed to mirror each other on two sides of the first bus line.

3. The photoelectric sensing device according to claim 1, wherein the first bus line does not overlap the first semiconductor layer and the second semiconductor layer in a normal direction of the substrate.

4. The photoelectric sensing device according to claim 1, wherein the first bus line comprises a bias line.

5. The photoelectric sensing device according to claim 1, further comprising:
a second bus line, disposed on the substrate and located between the first semiconductor layer and the second semiconductor layer,
wherein the second bus line does not overlap the first semiconductor layer and the second semiconductor layer in a normal direction of the substrate, and the second bus line at least partially overlaps the first bus line in the normal direction of the substrate.

6. The photoelectric sensing device according to claim 5, wherein the second bus line comprises an active load line or a reset signal line.

7. The photoelectric sensing device according to claim 1, further comprising a first bridge electrode and a second bridge electrode, wherein the first bus line is electrically connected to the first pixel structure through the first bridge electrode, and the first bus line is electrically connected to the second pixel structure through the second bridge electrode.

8. The photoelectric sensing device according to claim 7, wherein the first bus line, the first bridge electrode, and the second bridge electrode belong to a same layer.

9. The photoelectric sensing device according to claim 1, further comprising:
a third pixel structure, disposed on the substrate and comprising a third photoelectric sensing component, wherein the third photoelectric sensing component has a third semiconductor layer; and
a third bus line, disposed on the substrate and located between the first semiconductor layer and the third semiconductor layer, wherein the third bus line is electrically connected to the first pixel structure and the third pixel structure,
wherein the third bus line does not overlap the first semiconductor layer and the third semiconductor layer in a normal direction of the substrate,
wherein an extension direction of the third bus line is orthogonal to an extension direction of the first bus line.

10. The photoelectric sensing device according to claim 9, wherein the first pixel structure and the third pixel structure are disposed to mirror each other on two sides of the third bus line.

11. The photoelectric sensing device according to claim 9, wherein the third bus line comprises a reset signal line.

12. The photoelectric sensing device according to claim 9, further comprising a first bridge electrode, a second bridge electrode, and a third bridge electrode, wherein the first bus line is electrically connected to the first pixel structure through the first bridge electrode, the first bus line is electrically connected to the second pixel structure through the second bridge electrode, and the first bus line is electrically connected to the third pixel structure through the third bridge electrode.

13. The photoelectric sensing device according to claim 12, wherein the first bus line, the first bridge electrode, the second bridge electrode, and the third bridge electrode belong to a same layer.

14. The photoelectric sensing device according to claim 1, wherein the first pixel structure further comprises a first transistor, the second pixel structure further comprises a second transistor, the first transistor is coupled to the first photoelectric sensing component, and the second transistor is coupled to the second photoelectric sensing component.

15. The photoelectric sensing device according to claim 14, wherein one of the first transistor and the second transistor comprises a selection transistor, a driving transistor, and a reset transistor.

16. The photoelectric sensing device according to claim 15, wherein one of the first transistor and the second transistor further comprises a load transistor.

17. The photoelectric sensing device according to claim 11, wherein the third bus line comprises a global reset line.

18. The photoelectric sensing device according to claim 1, further comprising:
a first read line, extending along a first direction and electrically connected to the first pixel structure;
a second read line, extending along the first direction and electrically connected to the second pixel structure; and
a selection line, extending along a second direction and electrically connected to the first pixel structure and the second pixel structure,
wherein the first read line and the second read line are disposed to mirror each other on two sides of the first bus line.

19. The photoelectric sensing device according to claim 9, further comprising:
a first read line, extending along a first direction and electrically connected to the first pixel structure;
a second read line, extending along the first direction and electrically connected to the second pixel structure;
a first selection line, extending along a second direction and electrically connected to the first pixel structure; and
a second selection line, extending along the second direction and electrically connected to the second pixel structure,
wherein the first read line and the second read line are disposed to mirror each other on two sides of the first bus line,
wherein the first selection line and the second selection line are disposed to mirror each other on two sides of the third bus line.

20. The photoelectric sensing device according to claim 1, further comprising:
a first power line, electrically connected to the first pixel structure; and
a second power line, electrically connected to the second pixel structure.
